(19) United States
(12) Patent Application Publication
(10) Pub. No.: US 2004/0021454 A1
(43) Pub. Date: Feb. 5, 2004

(54) Capacitively coupled RF voltage probe

(75) Inventors: Jovan Jevtic, Milwaukee, WI (US); Andrej S. Mitrovic, Phoenix, AZ (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/611,907

(22) Filed: Jul. 3, 2003

Related U.S. Application Data
(63) Continuation of application No. PCT/US01/47488, filed on Dec. 17, 2001.
(60) Provisional application No. 60/259,862, filed on Jan. 8, 2001.

(51) Int. Cl. G01R 31/02; G01R 27/08

(52) U.S. Cl. 324/72.5; 324/713

(57) ABSTRACT

A voltage probe including a transmission line having an inner conductor and an outer conductor. An electrode is spaced apart from the outer conductor. A dielectric is disposed between the electrode and the outer conductor, adjacent an inner surface of the outer conductor. An exemplary method of implementing the voltage probe may include providing the dielectric adjacent the outer conductor. The electrode separated from the outer conductor by the dielectric and positioned adjacent to the dielectric is provided. A signal is measured from the electrode indicating a transmission voltage in the transmission line.

This application is a Continuation of International Application PCT/US01/47488, filed on Dec. 17, 2001, which, in turn, claims the benefit of U.S. Provisional Application 60/259,862, filed Jan. 8, 2001, the contents of both of which are incorporated herein by reference.

### FIELD OF THE INVENTION

The present invention generally relates to voltage and current measuring devices and more specifically to voltage and current measuring devices placed in RF transmission lines.

### BACKGROUND OF THE INVENTION

In the fabrication and processing of semiconductor wafers, such as silicon wafers, a variety of different semiconductor equipment and processes can be utilized. For example, wafer processing techniques are known in the art and may include, for example, photolithography, ion beam deposition, vapor deposition, etching, as well as a variety of other processes.

In one method of wafer processing, plasma generators are used to process a wafer, for example by etching a layer formed on the surface of the wafer. In employing this technique, electrical power is coupled to the plasma generator from an electrical source. Typically, the electrical energy has a frequency in the radio frequency (RF) range. Control of the process is performed in part by measuring and monitoring the RF signal. The power input into the system can be determined by measuring the RF voltage (V) and the RF current (I) components of the RF power source coupled to the plasma generator. It is generally desirable to obtain the voltage and current measurements as close to the plasma generator as possible in order to obtain a true representation of the actual RF voltage and current entering the plasma generator. Thus, a common practice for measuring RF power is to install a sensor for monitoring current and voltage in series with the transmission medium coupling the RF power to the plasma generator.

Sometimes, however, such RF monitors can disrupt the plasma process or may fail to obtain accurate indications of the ongoing plasma process. The monitor itself may affect the RF signal due to reflections, for example. Moreover, such techniques are not generally practiced in order to provide in-situ control of an ongoing manufacturing process.

Consequently, there exists a need for a voltage probe for sensing voltage in a device for monitoring a source of RF electrical power, which minimally intrudes in the RF transmission line in which the probe is placed.

### SUMMARY OF THE INVENTION

A need exists for improved measuring techniques of a signal, such as a RF signal, in a transmission line including an inner conductor and an outer conductor.

Therefore, an exemplary embodiment of the invention provides a voltage probe including a transmission line having an inner conductor and an outer conductor. An electrode is spaced apart from the outer conductor. A dielectric is disposed between the electrode and the outer conductor, adjacent an inner surface of the outer conductor.

An exemplary method of monitoring a voltage in a transmission line including an inner conductor and an outer conductor includes providing a dielectric adjacent the outer conductor and an electrode separated from the outer conductor by the dielectric and positioned adjacent to the dielectric. A signal is measured from the electrode indicating a transmission voltage in the transmission line.

Other objects, features and advantages of the present invention will become apparent from the following detailed description, the accompanying drawings, and the appended claims.

### BRIEF DESCRIPTION OF SEVERAL VIEWS OF THE DRAWINGS

The present invention is further described in the detailed description which follows, by reference to the noted drawings by way of non-limiting exemplary embodiments, in which like reference numerals represent similar parts throughout the several views of the drawings, and wherein:

FIG. 1 is a fragmentary view of a transmission line showing an exemplary voltage probe that can be employed, for example, to control a plasma process in accordance with the present invention;

FIG. 2 is an enlarged view of the exemplary voltage probe of the present invention shown in FIG. 1;

FIG. 3 is a fragmentary view of a cylindrical transmission line in which the first exemplary embodiment of the voltage probe is disposed in accordance with the present invention;

FIG. 4A is a block diagram illustrating a generator system and the exemplary voltage probe of the present invention within the generator system for measuring RF voltage, RF current, phase angle and DC bias voltage of a RF signal coupled to a generator;

FIG. 4B is a schematic diagram describing one embodiment for calibration of the exemplary voltage-current probe shown in FIG. 1;

FIG. 5 is a flow chart illustrating a method in accordance with an exemplary embodiment of the invention in which a signal is measured in a transmission line;

FIG. 6 is a flow chart illustrating a method in accordance with an exemplary embodiment of the invention in which a plasma process is controlled by RF monitoring, such as, for example, in the fabrication of semiconductor wafers; and

FIG. 7 is a fragmentary view of a transmission line showing another embodiment of the exemplary voltage probe that can be employed, for example, to control a plasma process in accordance with the present invention.

### DETAILED DESCRIPTION OF THE EMBODIMENTS

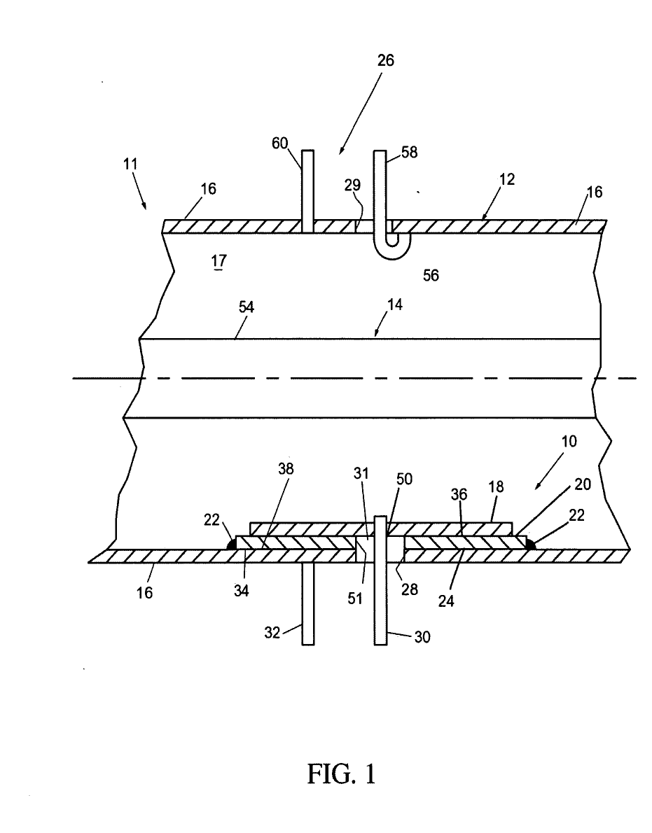

Referring to FIG. 1, in accordance with the present invention, there is provided an exemplary voltage probe that can be employed, for example, to control a plasma process in accordance with the present invention. The voltage probe, generally indicated at 10, may be incorporated as part of an RF probe 11 including both a voltage probe 10 and a current probe. The voltage probe 10 is incorporated into a transmission line 12 having an inner conductor 14, an outer conductor 16 and dielectric material 17 therebetween. The voltage probe 10 includes an electrode 18 and a dielectric 20. The electrode 18 is spaced apart from the outer conductor 16 by the dielectric 20 such that the electrode is not in direct electrical communication with the outer conductor 16. The electrode 18 essentially comprises a sheet of conductive material. The dielectric 20 is disposed adjacent an inner surface 24 of the outer conductor 16 between the electrode 18 and the outer conductor 16. The electrode 18 is therefore capacitively coupled to the transmission line 12. That is, the electrode 18, the dielectric 20 and the outer conductor 16 together form a capacitor. If the electrode 18 is constructed to conform to the geometry of the outer conductor 16, the combination essentially forms a parallel plate capacitor.

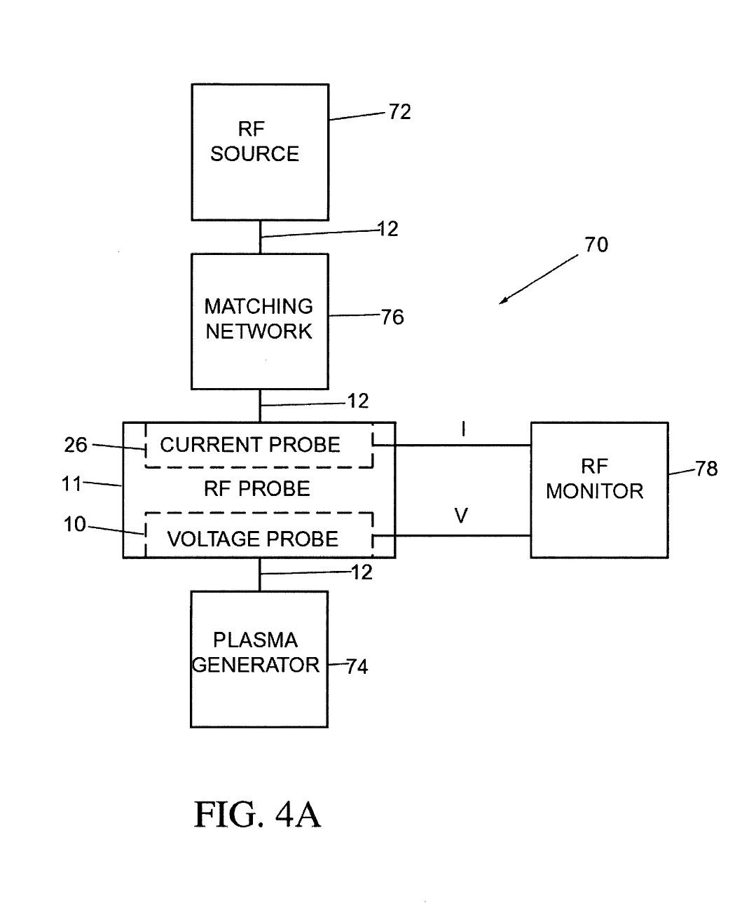

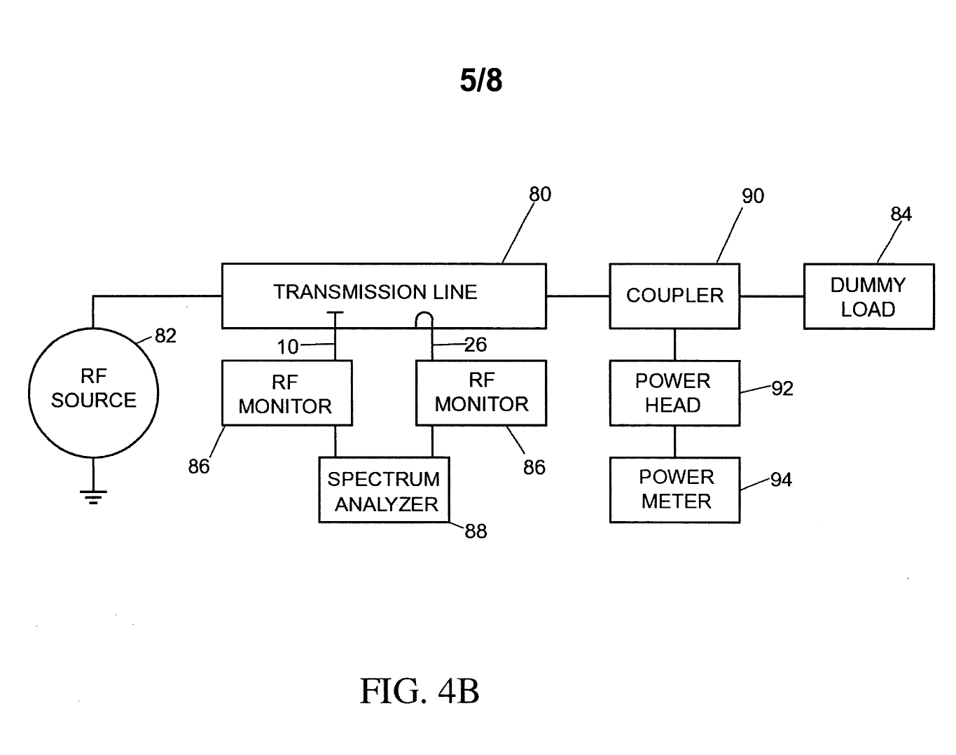

As illustrated, the RF probe 11 includes a current sensor 26 (illustrated schematically in FIG. 4) for measuring current. The RF voltage is sampled or sensed by the voltage probe 10 and the RF current is sampled or sensed by the current probe or sensor 26. In order to accurately monitor phase information, the current probe 26 can be located nominally in the same transverse plane of the transmission line 12 as the voltage probe 10 and in diametrically opposing relation therewith. Since the characteristic wavelength of the electrical signals is large compared to the voltage probe, the current probe need not be precisely in the same transverse plane, but the distance from the plane should be small relative to the wavelength. That is, the current probe 26 is configured to measure a current at a point proximate a plane transverse to the transmission line 12 and passing through the outer conductor 16.

Since the voltage probe 10 electrode 18 has a finite length, it may be difficult to position the current probe exactly in a plane therewith. As a result, a convenient approximation may be used. For example, the current probe 26 may be arranged to monitor a current in the transmission line 12 at a point proximate a plane transverse to the transmission line 12 passing through the center of the electrode 18. A signal measured from the current probe may indicate a transmission current in the transmission line 12.

In typical RF transmission lines used for semiconductor processing, the fundamental RF frequency at which power is coupled to the plasma can be, for example, 60 megahertz (MHz). Harmonic frequencies with respect to the fundamental RF frequency are also inherently present due to the plasma non-linearity. For example, for a fundamental frequency of 60 MHz, harmonic frequencies with appreciable power can be as high as 300 MHz (i.e., 5^{th} harmonic), and have a characteristic wavelength on the order of 1 meter.

FIG. 1 shows the current probe 26 positioned within the transmission line 12 to monitor a current proportional to the current flowing through the transmission line 12 at a point which is within a distance equal to or less than 3%, e.g., 1 to 3%, the characteristic wavelength from the plane transverse to the transmission line 12 passing through the center of the electrode 18. The characteristic wavelength may be the wavelength associated with the highest frequency or smallest wavelength to be measured. For example, if the maximum frequency to be measured is 300 MHz, then the spacing between the current sensor 26 and the center of the voltage probe 10 should not exceed 1 to 3% of the characteristic wavelength at 300 MHz, which may be approximately one meter, or 1 to 3 cm. This distance may fluctuate depending on user requirements and application, such as, for example, being a distance greater than or less than that described above in order to produce a more or less specific measurement, e.g., one which gives more accurate phase information, respectively.

In one embodiment, the electrode 18 overlies the dielectric 20 and the dielectric 20 extends outward beyond oppositely facing edges of the electrode 18. This configuration reduces the possibility of a short circuit, particularly if conductive solder collects near ends of the dielectric during the process of mounting the voltage probe 10 within the transmission line 12. The electrode 18 may have a length small compared to one-fourth of the characteristic wavelength of the RF signal to be measured. For example, the voltage probe 10 may be 2 cm in length and employed to measure RF signals with frequencies as high as 1 GHz. In one embodiment, the length of the voltage probe 10 is approximately 1/15^{th} of the characteristic wavelength at 1 GHz.

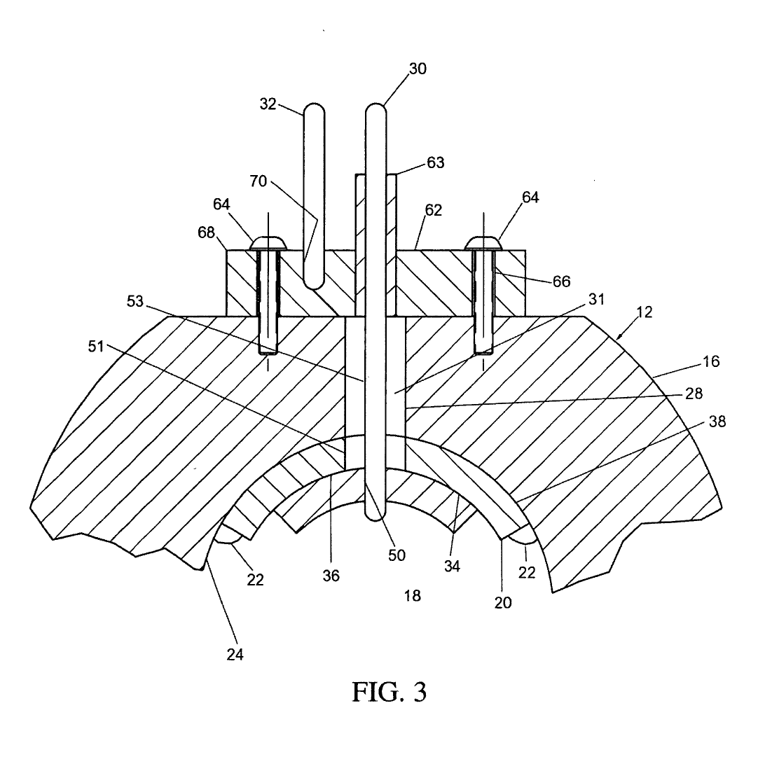

Additionally, the electrode 18 may be curved so as to correspond to the radius of curvature of the outer conductor 16 in the transmission line 12 (FIG. 3). Likewise, the dielectric 20 may also be curved so that the electrode 18 and the dielectric 20 are each configured as sections of cylindrical surfaces. Since the transmission line 12 is commonly cylindrical, each of the dielectric 20 and the electrode 18 can take the form of cylindrical surfaces having smaller radii, thereby forming a curved parallel plate capacitor. For example, in one embodiment, the thickness of the dielectric 20 and the electrode 18 are approximately 25 mils and 1 mil, respectively.

A suitable material for manufacturing the electrode 18 and dielectric 20 is manufactured by Rogers Corporation and sold under the product name, Rogers RT/duroid® type 5880. This material comprises a microwave laminate with electrodeposited copper on only one surface, thus the laminate forms the dielectric 20 and the copper layer forms the electrode 18.

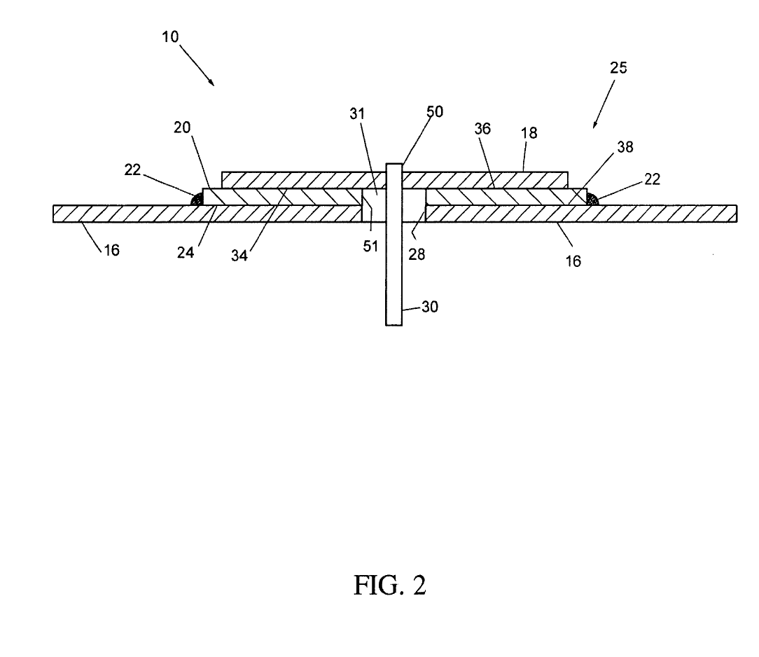

For introducing the voltage probe 10 and the current probe 26, a pair of holes 28, 29 are formed in opposite sides of the outer conductor 16 so that a lead 30 may pass through hole 28, as best shown in FIGS. 1 and 2. A second lead in the form of a coil loop 56 passes through the hole 29, as will be described below.

In this embodiment, the lead 30, which may be a wire or metal rod, passes through the hole 28 and through a hole 51 in the dielectric 20 and is in electrical communication with the electrode 18. Insulating material 31, such as air, plastic, quartz or alumina, may surround the lead 30 to ensure a tight fit within the hole 28. A free end portion of the lead 30 may extend past the electrode 18 so that the free end portion may be soldered to the electrode 18 to firmly secure the lead 30 to the electrode 18. A second lead 32 is connected to the outer conductor 16. The leads 30 and 32 cooperatively couple the voltage probe 10 to a measuring device, such as high impedance RF monitor 78, illustrated in FIG. 4, thereto.

As illustrated in FIG. 1, an inner surface 34 of the dielectric 20, which is the upper surface in FIG. 1, is attached to the electrode 18. The dielectric 20 may be attached (by bond 22) to an underside or inner surface 36 of the electrode 18 using, for example, an epoxy resin. When using Rogers RT/Duroid ® type 5880, bonding the inner surface 34 of the dielectric 20 and the inner surface 36 of the electrode 18 is not necessary since a bonded interface between the dielectric 20 and the electrode 18 may be achieved during an electroplating process. Outer surface 38 of the dielectric 20, which is the copper-free surface opposing the outer surface 34, may be bonded to the inner surface 24 of the outer conductor 16 by bond 22, which can be an adhesive, such as epoxy resin, or other sufficient bonding means.

The configuration and use of the current probe 26 will now be described.

A typical mode of electromagnetic (EM) wave propagation in a cylindrical coaxial transmission line, such as transmission line 12, is such that the direction of the oscillating electric field is in the radial direction between the inner and outer conductors 14 and 16, respectively, and the direction of the oscillating magnetic field is in the azimuthal direction through the region between the inner and outer conductors 14 and 16 respectively. For example, if a loop antenna 56 is disposed within the coaxial transmission line 12 to be positioned between the inner and outer conductors 14 and 16, respectively, such that the surface normal to the area formed by the loop is tangential to the magnetic field lines, then the magnetic field lines intercepted by the loop antenna 56 induce a measurable current in the loop antenna. The measured current is proportional to the magnetic flux through the loop antenna 56 which is, in turn, related to the current flowing through the transmission line 12. Using this effect, the current flowing through the transmission line may be measured.

A current probe 26 includes the loop antenna 56 coupled to the inner surface 24 of the outer conductor 16 and a generally straight lead 58 integrally coupled to the loop antenna 56. The lead 58 extends radially outwardly away from the loop antenna 56, through the hole 29 in the outer conductor 16. Another lead 60 is coupled to the outer conductor 16 so as to extend outwardly therefrom. The leads 58, 60 cooperatively couple the current probe to a measuring device such as high impedance RF monitor 78 as shown in FIG. 4.

In this embodiment, the loop antenna 56 is disposed within the transmission line 12 through the hole 29 in the outer conductor 16 (the upper side of the outer conductor 16 in FIG. 1). The current loop is configured to measure the RF current in the transmission line 12. As described above, the magnetic flux intercepted by the loop antenna 56, which is associated with the transmission line 12, induces a current and voltage in the loop antenna 56. The induced voltage is then used to determine the current flowing through the conductors 14, 16 which is related according to the geometry of the transmission line and the loop itself. More detail of the operation of a loop antenna current probe can be found in U.S. Pat. No. 5,867,020. Though a loop antenna current probe is disclosed herein, any other appropriate type of current measuring device may be used.

FIG. 3 shows the RF transmission line 12 having a cylindrical cross-section with the voltage probe 10 mounted therein. The hole 28, which may be drilled in the outer conductor 16, receives the insulation bead or material 31. The hole 28 and the holes 50, 51 in the electrode 18 and the dielectric 20, respectively, are aligned such that the lead 30 may pass therethrough and be secured to the electrode 18, as described above. The insulating bead 31 is inserted into the hole 28 in the outer conductor 16 and has a vertically extending axial opening 53 centrally formed therein. The insulating bead 31 is retained in opening 28 by a cover plate 62, which is attached to RF transmission line 12 by a number of fasteners 64 that extend through fastener receiving openings 66 in the cover plate 62. The fasteners 64 may be nuts and bolts, machine screws or any other fastening means capable of securing the cover plate 62 to the transmission line 12. The lead 30 may be inserted through the axial opening 53 and may be insulated with insulation cover 63. Insulators 31 and 63 may be made from a one-piece construction.

The lead 30 may extend beyond the outer end of insulating bead 31 and the lead 32 may extend outward from an outer surface 68 of cover plate 62. As may be appreciated, the lead 32 may actually extend to the outer conductor 16 if desired, however, in the case that the cover plate 62 is conductive, it may be simpler to connect the lead 32 to the cover plate rather than to the outer conductor 16 without affecting the measurement. The center-to-center distance between lead 30, which may be a conducting wire, and lead 32 is sufficient to facilitate the use of the high impedance RF monitor 78, which may be, for example, a Tektronix P6245 1.5 GHz 10×Active Probe manufactured by Tektronix, for measurement of the RF voltage in RF transmission line 12. A sufficient center-to-center distance may be 0.20 inches or 5.0 millimeters. The lead 32 may extend through a hole 70 in the cover plate 62 and be coupled to the cover plate 62 or the outer conductor 16, e.g., by soldering. Lead 30 may extend through holes 28, 50 and 51 to make electrical contact with electrode 18, wherein the physical connection is secured, for example, via bond 22.

Other arrangements for connecting to the leads 30 and 32 of the voltage probe 10 in RF transmission line 12 are also possible. For example, any of a number of RF jacks may be used instead of the high impedance RF monitor 78, however, the high impedance RF monitor 78 reduces the electrical loading effect on the voltage probe 10. By use of a sufficiently high impedance, the voltage probe 10 may provide precise measurements and reduce reflections in the transmission line due to the probe.

FIG. 4A shows the voltage probe 10 employed, for example, to control a plasma process in a plasma system 70 in accordance with an embodiment of the invention. In plasma system 70, an electrical source, such as RF source 72, is coupled to a plasma generator 74 through a matching network 76 by a transmission line 12. The plasma generator 74 can be any of a variety of generators, such as a capacitively coupled or inductively coupled plasma generator for use in plasma deposition or plasma etch processing of, for example, a semiconductor wafer such as a silicon wafer. However, other processing systems utilizing electrical or microwave energy (including RF) sources can be advantageously controlled according to the method of the present invention.

As illustrated, the RF probe 11 including the voltage probe 10 of the present invention is disposed in the transmission line 12. The RF probe 11 may be disposed between the matching network 76 and the plasma generator 74 so as to be proximal to the plasma generator 74. Alternatively, the voltage probe 10 may be positioned between the RF source 72 and the matching network 76 in situations where a potential power loss in the matching network 76 needs to be determined.

If the voltage probe 10 is positioned in close proximity to the generator 74, the measurements obtained from voltage probe 10 are indicative of actual transmission voltage (V) values entering the generator 74.

In order to measure the actual RF voltage and current, the voltage probe 10 and current probe 26 may be calibrated prior to use in the system described in FIG. 4B.

FIG. 4B describes an apparatus for calibrating the RF voltage and current probes, 10 and 26, respectively. As illustrated, the voltage probe 10 and the current probe 26 are installed in a coaxial transmission line 80, such as a 50 Ohm coaxial transmission line, through which RF power from RF source 82, for example, having 50 Ohm output impedance, is coupled to a dummy load 84, for example, being a 50 Ohm dummy load. The RF source 82 may comprise a frequency sweeping signal generator and a broadband amplifier. One suitable dummy load 84 is manufactured by Altronic Research and sold as Model # 9725E3.

A high impedance RF monitor 86, such as Tektronix P6245 1.5 GHz 10×Active Probe manufactured by Tektronix, is connected to each of the voltage probe 10 and the current probe 26, such that the output may be recorded on a spectrum analyzer 88. One suitable spectrum analyzer is manufactured by Hewlitt-Packard and sold under the name Network Spectrum Analyzer having model number 4396A. A coupler 90, for example, a 63 dB coupler, may be inserted between the coaxial transmission line 80 and the dummy load 84. One suitable coupler is manufactured by Amplifier Research having model number DC6280. As shown in FIG. 4B, the attenuated signal from the coupler 90 is connected to a power head 92 and a power meter 94 to record the power. One suitable power head 92 and power meter 94 may be manufactured by Amplifier Research having model numbers PH2000 and PH2002, respectively.

Using the measured power (P_{RF}) from the power meter 94 and the known transmission line impedance, Z_{RF}, such as 50 Ohms, the amplitude of the RF voltage (V_{RF}) and RF current (I_{RF}) can be inferred from the formula P_{RF}=V_{RF}*I_{RF} and Z_{RF}=V_{RF}/I_{RF}. For a given frequency, the calibration coefficients K_{V} and K_{I} can be determined from the ratio of the measured amplitude of the RF voltage (V) recorded using voltage probe 10 to the measured voltage (V_{RF}) inferred from the RF power measured with power meter 94 and the measured amplitude of the RF current (I) recorded using current probe 26 to the measured current (I_{RF}) inferred from the RF power measured with power meter 94, respectively. In general, K_{V} tends to be invariant with change in frequency ( [symbol] and K_{I}, increases approximately linearly with frequency ( [symbol] . After sweeping the frequency from RF source 82, the frequency dependence of the calibration coefficients K_{V} and K_{I} can be recorded. The two calibration curves (i.e. K_{V} vs. □ and K_{I} vs. □) can be used to calibrate the measured RF signals using the voltage probe 10 and the current probe 26, such as, at a later time. The measured RF signals can, in general, comprise a plurality of frequencies, hence, the calibration may be performed in frequency space or Fourier space.

A high impedance RF monitor 78 may be coupled to the RF probe 11 via the voltage outputs (leads 30, 32) from the voltage probe 10 and current outputs (leads 58, 60) from the current probe 26. The transmission voltage (V) in the transmission line 12 is measured from the leads 30, 32 and the transmission current (I) in the transmission line 12 is measured from the leads 58, 60 of the current probe 26.

Both voltage and current values are sensed at substantially the same point or position in the transmission line 12. These voltage and current values may be used to determine the power entering the generator 74, to determine the phase angle between the voltage and current, or to determine the line impedance.

RF probe 11 including the voltage probe 10 and the current probe 26 may be used to control the performance of plasma by controlling the RF source 72 and the plasma generator 74 in conjunction with a computer (not shown) including a Graphical User Interface (GUI), e.g., a mouse, touch screen, keyboard, or a display. The plasma system 70 may be controlled in real-time for providing in-situ control.

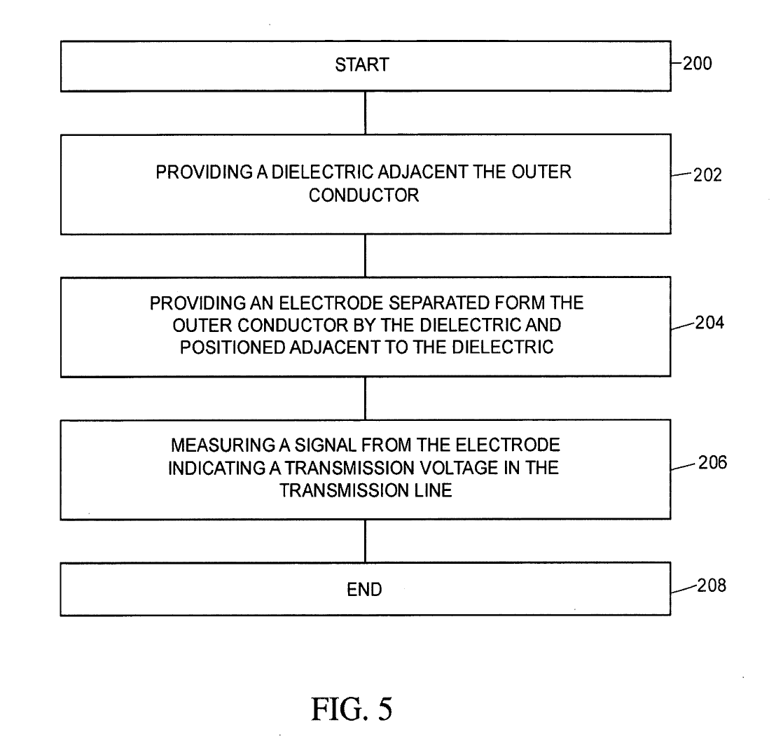

FIG. 5 illustrates a method for measuring a signal in the transmission line 12. The method begins at 200 and the control sequence proceeds to 202. At 202, the dielectric 20 is provided adjacent the outer conductor 16. Control then proceeds to 204, at which the electrode 18 is provided. Control then proceeds to 106. At 206, a signal is measured from the electrode 18 indicating the transmission voltage (V) in the transmission line 12. The signal may be calibrated using the above-described calibration procedure. Control directly proceeds to 208, at which the method ends.

The method shown in FIG. 5 may also include providing the current probe 26, measuring the current (I) at a point proximate a plane transverse to the transmission line 12 and passing through the electrode 18, and measuring a signal from the current probe 26 indicating a transmission current (I) in the transmission line 12.

The method shown in FIG. 5 may include other auxiliary operations, such as calculating any one or more of phase, power and impedance information using the measured signal from the electrode and the measured signal from the current probe.

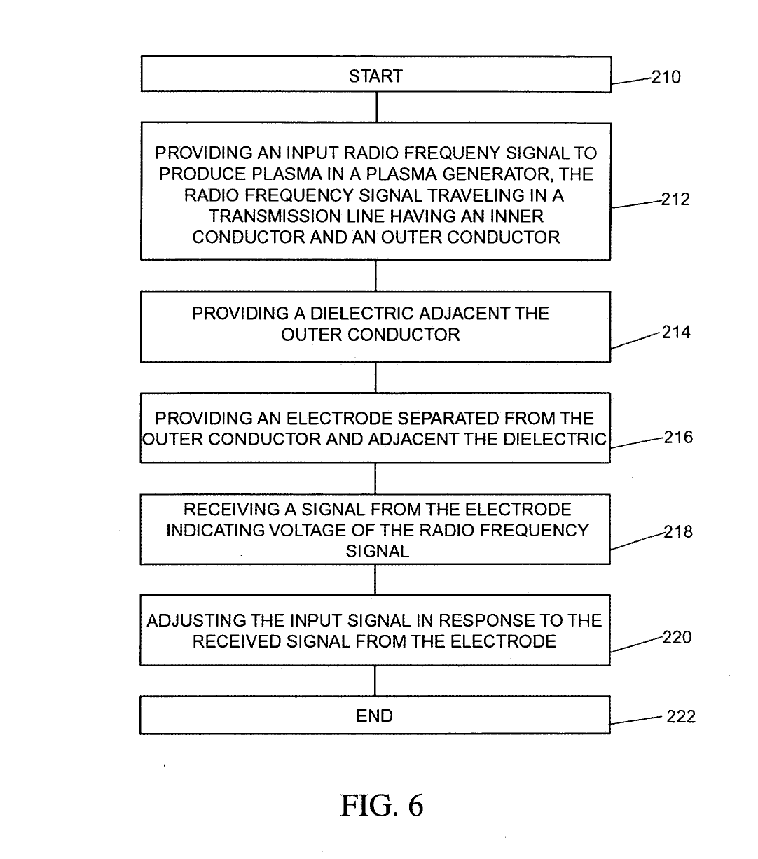

A technique utilizing the voltage probe 10 in the RF probe 11 for providing radio frequency (RF) monitoring to control the plasma process 70, which may be utilized in the fabrication of semiconductor wafers, is illustrated in FIG. 6. The method begins at 210. At 212, an input radio frequency (RF) signal to produce a plasma in the plasma generator 74 is provided by RF source 72. The radio frequency (RF) signal travels in the transmission line 12. At 214, the dielectric 20 is provided adjacent the outer conductor 16 of the transmission line 12. At 216, the electrode 18 is provided. The electrode 18 is separated from the outer conductor 16 and adjacent the dielectric 20. At 218, a signal is received from the electrode indicating the voltage of the radio frequency (RF) signal. The signal may be calibrated using the above-described calibration procedure. At 220, the input signal is adjusted in response to the received signal from the electrode 18 so as to control the plasma process 70. At 222, the method ends.

The method illustrated in FIG. 6 may also include operations for measuring a current of the radio frequency (RF) signal and adjusting the input signal in response to the measured current.

In the above description, numerous specific details are set forth, such as specific devices, components, measuring techniques, etc., in order to provide a thorough understanding of the present invention. However, it will be appreciated by one skilled in the art that the present invention may be practiced without these specific details. In other instances, well known techniques and structures have not been described in detail in order not to obscure the present invention.

Although the RF probe 11 is described hereinabove as including the voltage probe 10 and the current probe 26 for obtaining voltage and current samples at about the same location on the transmission line 12 for determining RF power supplied to an electrical load, such as the plasma generator 74 and plasma, the current probe 26 is not required and only the voltage probe 10 may be necessary to effectively practice the invention.

While the principles of the invention have been made clear in the illustrative embodiments set forth above, it will be apparent to those skilled in the art that various modifications may be made to the structure, arrangement, proportion, elements, materials, and components used in the practice of the invention

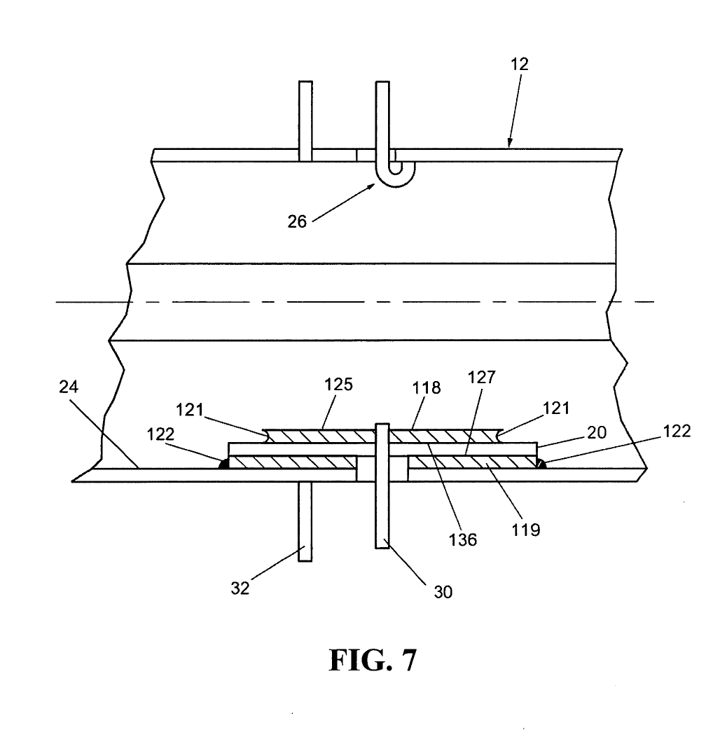

For example, FIG. 7 illustrates a voltage probe 110 disposed within the transmission line 12. The voltage probe 110 is similar in construction and operation to the voltage probe 10 and the description relating to the voltage probe 10 will suffice for both, except that the voltage probe 110 includes a first electrode 118 and a second electrode 119, rather than just electrode 18. The first and second electrodes 118, 119 are disposed on opposite sides of the dielectric 20 such that the dielectric 20 is disposed between the electrode 118 and each of the second electrode 119 and the outer conductor 16. The dielectric 20 may be bonded, e.g., by sweat soldering or any other bonding means, to the inner surface 136 of the first electrode 118 and to the inner surface 127 of the second electrode 119. Lead 32 may extend through the outer conductor 16 to contact the second electrode 119 if a good electrical contact between electrode 119 and outer conductor surface 24 is not achieved otherwise the lead 32 may connect to the outer conductor 16

Just as in the previously described embodiments, the electrode 118, the electrode 119 and the dielectric 20 would constitute a capacitor 125 in which the electrode 118 overlies the dielectric 20 and the dielectric 20 extends outward beyond oppositely facing edges of the electrode 118. The extended configuration of the dielectric reduces the likelihood of the capacitor 125 being short-circuited when mounted into the transmission line 12. FIG. 7 shows the electrode 119 being soldered to the outer conductor 16 via solder 122. Excess solder 122 may form about the base of electrode 119 and dielectric 20, which could short-circuit the capacitor 125. Recesses 121 formed in the outer edge of electrode 118 help avoid either direct contact with the excess solder or arcing to the solder.

Since the second electrode 119 along the inner surface 24 of the outer conductor 16 is in conducting contact with the outer conductor 16, this embodiment will operate in a manner similar to the above described embodiments and the second electrode 119 will have a negligible effect on voltage measurements.

A suitable capacitor 125 may be manufactured by Rogers Corporation under the product name, Rogers RT/duroid® type 5880 microwave laminate. Similar to the electrode 18, the first and second electrodes 118, 119 may be curved to correspond to the radius of curvature of the transmission line 12.

Additionally, the voltage probes 10, 110 may be readily adapted for use with other transmission media, other than coaxial cables, such as strip lines.

It will thus be seen that the objects of this invention have been fully and effectively accomplished. It will be realized, however, that the foregoing embodiments have been shown and described for the purpose of illustrating the functional and structural principles of this invention and are subject to change without departure from such principles. Therefore, this invention includes all modifications encompassed within the spirit and scope of the following claims.

What is claimed is:

1. A voltage probe comprising:
a transmission line having an inner conductor and an outer conductor;
an electrode, spaced apart from the outer conductor; and
a dielectric, disposed between the electrode and the outer conductor, adjacent an inner surface of the outer conductor.

2. A voltage probe as in claim 1, further comprising a lead in electrical communication with the electrode, the lead passing through an opening through each of the dielectric and the outer conductor.

3. A voltage probe as in claim 1, wherein each of the outer conductor and the electrode are curved.

4. A voltage probe as in claim 1, wherein the dielectric is attached to the electrode and the inner surface of the outer conductor.

5. A voltage probe as in claim 1, wherein the electrode overlies the dielectric and the dielectric extends outward beyond the edges of the electrode.

6. A voltage probe as in claim 1, wherein the electrode and the dielectric are each configured as sections of cylindrical surfaces.

7. A voltage probe as in claim 1, further comprising:
a current probe, arranged to monitor a current in the transmission line at a point proximate a plane transverse to the transmission line passing through the center of the electrode.

8. A voltage probe as in claim 1, further comprising a current probe, wherein a current to be measured by the current probe has a characteristic wavelength and the probe is positioned to monitor the current in the transmission line at a point which is within a distance equal to or less than 3% the characteristic wavelength from the plane transverse to the transmission line passing through the center of the electrode.

9. A voltage probe as in claim 1, wherein the electrode has a length small compared to one-fourth of a characteristic wavelength of a signal to be measured.

10. A voltage probe as in claim 1, further comprising:
a second electrode, spaced apart from the first mentioned electrode such that the dielectric is disposed between the first mentioned electrode and the second electrode and adjacent an inner surface of the outer conductor.

11. A voltage probe as in claim 10, wherein each of the outer conductor, the first mentioned electrode and the second electrode are curved.

12. A voltage probe as in claim 10, wherein the first mentioned electrode, the second electrode, and the dielectric are each configured as sections of cylindrical surfaces.

13. A voltage probe as in claim 10, further comprising:
a current probe, arranged to monitor a current in the transmission line at a point proximate a plane transverse to the transmission line passing through the center of the electrode.

14. A method of measuring a signal in a transmission line including an inner conductor and an outer conductor, comprising:
providing a dielectric adjacent the outer conductor;
providing an electrode separated from the outer conductor by the dielectric and positioned adjacent to the dielectric; and
measuring a signal from the electrode indicating a transmission voltage in the transmission line.

15. A method as in claim 14 further comprising:
providing a current probe, configured to measure a current at a point proximate a plane transverse to the transmission line and passing through the electrode; and
measuring a signal from the current probe indicating a transmission current in the transmission line.

16. A method as in claim 15 further comprising;
calculating any one or more of phase, power and impedance information using the measured signal from the electrode and the measured signal from the current probe.

17. A method as in claim 16 wherein the electrode is small compared to one-fourth of a characteristic wavelength of a signal to be measured.

18. A method of controlling a plasma process, comprising:
providing an input radio frequency signal to produce a plasma in a plasma generator, the radio frequency signal traveling in a transmission line having an inner conductor and an outer conductor;
providing a dielectric adjacent the outer conductor;
providing an electrode separated from the outer conductor and adjacent the dielectric;
receiving a signal from the electrode indicating voltage of the radio frequency signal; and
adjusting the input signal in response to the received signal from the electrode.

19. A method as in claim 18 further comprising:
measuring a current of the radio frequency signal; and
adjusting the input signal in response to the measured current.
